(19) United States
(12) Patent Application Publication
(10) Pub. No.: US 2024/0057263 A1
(43) Pub. Date: Feb. 15, 2024

(54) METHOD FOR PRODUCING WIRING BOARD, LAMINATE AND METHOD FOR PRODUCING SAME

(71) Applicant: Resonac Corporation, Minato-ku, Tokyo (JP)

(72) Inventors: Masaya TOBA, Minato-ku, Tokyo (JP); Masaki YAMAGUCHI, Minato-ku, Tokyo (JP); Kazuyuki MITSUKURA, Minato-ku, Tokyo (JP)

(21) Appl. No.: 18/260,468

(22) PCT Filed: Jan. 6, 2021
(86) PCT No.: PCT/JP2021/000218

§ 371 Date: Jul. 5, 2023

(51) Int. Cl. H05K 3/18; H05K 3/10; H05K 3/02

(52) U.S. Cl. CPC H05K 3/181; H05K 3/107; H05K 3/025

(57) ABSTRACT

A method for manufacturing a wiring board including: providing a laminate including an insulating material layer and a copper layer provided on a surface of the insulating material layer, and in which the copper layer is an electroless copper plating layer; forming a resist pattern including a groove reaching a surface of the copper layer on the surface of the copper layer; and filling the groove with a conductive material containing copper by electrolytic copper plating. The thickness of the electroless copper plating layer is, for example, 20 nm to 200 nm.

### TECHNICAL FIELD

The present disclosure relates to a method for manufacturing a wiring board, a laminate comprising an electroless copper plating layer and a method for manufacturing thereof, and a copper layer with carrier.

### BACKGROUND ART

In order to realize high density and high performance of a semiconductor package, a mounting aspect in which semiconductor elements (hereinafter, sometimes referred to as “chips”) different in performance are mixedly mounted in one package is suggested. High-density interconnect technology between chips is becoming more important From the viewpoint of the cost (referred to Patent Literature 1).

A connection method called package on package has been widely used in smartphones and tablet terminals. The package on package is a method for connecting another package on a package by flip-chip mounting (refer to Non-Patent Literature 1 and Non-Patent Literature 2). As aspects for higher-density mounting, there are suggested a package technology (organic interposer) using an organic board including high-density wirings, a fan-out type package technology (FO-WLP) including through mold vias (TMV), a package technology using a silicon or glass interposer, a package technology using through silicon via (TSV), a package technology using chips embedded in a board for inter-chip transmission, and the like. Particularly, in the organic interposer, and the FO-WLP, in a case where chips are mounted in parallel, a fine wiring layer is necessary for high-density conduction (refer to Patent Literature 2).

### CITATION LIST

### Patent Literature

Patent Literature 1: Japanese Unexamined Patent Publication No. 2003-318519
Patent Literature 2: U.S. Patent Application Publication No. 2001/0221071

### Non Patent Literature

Non Patent Literature 1: Application of Through Mold Via (TMV) as PoP Base Package, Electronic Components and Technology Conference (ECTC), 2008
Non Patent Literature 2: Advanced Low Profile PoP Solution with Embedded Wafer Level PoP (eWLB-PoP) Technology, ECTC, 2012

### SUMMARY OF INVENTION

### Technical Problem

By the way, according to examination made by the present inventors, in a case where a conductive portion (for example, a fine wiring) of the wiring board is formed by electrolytic copper plating, continuity between a seed layer and an electrolytic copper plating layer may be insufficient due to a crystal state of a metal layer constituting the seed layer. For example, in a case of forming fine wirings on a surface of copper foil formed with rolling by electroless copper plating, a discontinuous interface is interposed between the copper foil and an electroless copper plating layer. Therefore, in a case of forming finer wirings, there is a room for improvement in terms of reliability.

Here, the present disclosure provides a method for manufacturing a wiring board with excellent reliability. In addition, the present disclosure provides a laminate applicable to the manufacturing method and a manufacturing method thereof, and a copper layer with carrier.

### Solution to Problem

An aspect of the present disclosure relates to a method for manufacturing a wiring board. The manufacturing method comprises the following processes:

(A1) providing a laminate comprising an insulating material layer and a copper layer provided on a surface of the insulating material layer, wherein the copper layer is an electroless copper plating layer,

(A2) forming a resist pattern including a groove reaching a surface of the copper layer on the surface of the copper layer, and

(A3) filling the groove with a conductive material containing copper by electrolytic copper plating.

According to examination made by the present inventors, when electrolytic plating is performed on the surface of the electroless copper plating layer, continuity of an interface between the electroless copper plating layer and the electrolytic copper plating layer is excellent and both the layers can secure excellent adhesiveness. According to the manufacturing method, it is possible to constitute a fine wiring by a conductive material obtained by the electrolytic copper plating and the copper layer (electroless copper plating layer) that is in contact with the conductive material. According to this, it is possible to manufacture a wiring board comprising fine wirings with excellent reliability.

A method for manufacturing a wiring board according to the present disclosure may be an aspect of manufacturing a multilayer wiring board comprising interlayer conductive portion. The manufacturing method according to this aspect comprises the following processes:

(B1) providing a laminate comprising a support board, an insulating material layer, and a copper layer in order, wherein the copper layer is an electroless copper plating layer,

(B2) forming a first opening reaching a surface of the support board through the copper layer and the insulating material layer,

(B3) forming a seed layer on a surface of a side wall of the first opening by electroless copper plating,

(B4) forming a resist pattern including a second opening communicating with the first opening on a surface of the copper layer, and

(B5) filling the first opening and the second opening with a conductive material containing copper by electrolytic copper plating.

According to the manufacturing method, the interlayer conductive portion can be constituted by the conductive material obtained by the electrolytic copper plating and the copper layer (electroless copper plating layer) that is in contact with the conductive material. According to this, it is possible to manufacture a wiring board comprising a conductive portion with excellent reliability. The reason for this is estimated because the conductive material and the copper layer have high continuity at the interface therebetween as described above.

The thickness of the copper layer (electroless copper plating layer) is, for example, 20 to 200 nm. Since the thickness of the copper layer is smaller in comparison to copper foil or a copper layer obtained by electrolytic copper plating, the copper layer is useful for further miniaturization of wiring. Since the thickness of the copper layer is extremely thin, in the manufacturing processes of the wiring board, an unnecessary portion of the copper layer can be efficiently removed by etching. According to this, labor required for the work can be reduced, and time can be shortened. In addition, it is possible to suppress occurrence of a variation in a cross-sectional area of the fine wiring due to the etching process.

The laminate in the process (B1) can be prepared, for example, through the following processes:

(b1) providing a copper layer with carrier which comprises the copper layer that is an electroless copper plating layer and a carrier provided in a peelable manner with respect to the copper layer,

(b2) pasting the copper layer onto a surface of the insulating material layer, and

(b3) peeling the carrier from the copper layer.

When selecting a carrier composed of a material suitable for electroless copper plating and forming a copper layer on a surface of the carrier by electroless copper plating, the copper layer having a sufficiently uniform thickness can be formed on the surface of the carrier. In contrast, in a case of forming the copper layer directly on the surface of the insulating material layer by electroless copper plating without using the carrier, it may be difficult to form the copper layer having a sufficiently uniform thickness due to a surface state (for example, low wettability), or adhesiveness of the copper layer with respect to the insulating material layer may not be sufficiently obtained.

According to an aspect of the present disclosure, there is provided a laminate. The laminate comprises an insulating material layer and a copper layer provided on a surface of the insulating material layer. The copper layer is an electroless copper plating layer. According to an aspect of the present disclosure, there is provided a copper layer with carrier. The copper layer with carrier comprises a copper layer formed by electroless copper plating, and a carrier provided in a peelable manner with respect to the copper layer.

### Advantageous Effects of Invention

According to the present disclosure, a method for manufacturing a wiring board with excellent reliability is provided. In addition, according to the present disclosure, a laminate applicable to the manufacturing method and a manufacturing method thereof, and a copper layer with carrier are provided.

### BRIEF DESCRIPTION OF DRAWINGS

FIG. 1 is a cross-sectional view schematically illustrating an embodiment of a copper layer with carrier according to the present disclosure.

FIG. 2 is a cross-sectional view schematically illustrating an embodiment of a laminate according to the present disclosure.

(a) to (c) in FIG. 3 are cross-sectional views schematically illustrating manufacturing processes of a wiring board.

(a) to (c) in FIG. 4 are cross-sectional views schematically illustrating manufacturing processes of the wiring board.

(a) to (c) in FIG. 5 are cross-sectional views schematically illustrating manufacturing processes of the wiring board.

### DESCRIPTION OF EMBODIMENTS

Hereinafter, an embodiment of the present disclosure will be described in detail with reference to the accompanying drawings. In the following description, the same reference numeral will be given to the same or equivalent portions, and redundant description will be omitted. In addition, positional relationships such as up, down, right, and left are based on positional relationships shown in the drawings unless otherwise stated. Dimensional ratios in the drawings are not limited to illustrated ratios.

Terminologies such as “left”, “right”, “front”, “rear”, “up”, “down”, “upward”, and “downward” are used in the description and the appended claims of this specifications, the terminologies are meant to be illustrative and do not necessarily mean that the terminologies are in the relative positions forever. In addition, a terminology “layer” also includes a shape structure formed partially in addition to a shape structure formed on an entire surface when being observed as a plan view. “A or B” may include any of A and B or may include both A and B.

A term “process” in this specification includes not only an independent process but also a process of which an intended operation is achieved although the process is not clearly distinguished from other processes. In addition, a numerical value range expressed by “to” indicates a range including numerical values described before and after “to” as a minimum value and a maximum value.

With regard to the content of each component in a composition in this specification, in a case where a plurality of materials corresponding to the component exist in the composition, the content represents a total amount of the plurality of materials existing in the composition unless otherwise stated. In addition, an exemplified material may be used alone unless otherwise stated, or two or more kinds may be used in combination. In addition, in a numerical range described stepwise in this specification, an upper limit value or a lower limit value of the numerical value range of any stage may be replaced with an upper limit value or a lower limit value of a numerical value range of another stage. In addition, in the numerical value range described in this specification, an upper limit value or a lower limit value of the numerical value range may be replaced with a value described in examples.

[Copper Layer with Carrier]

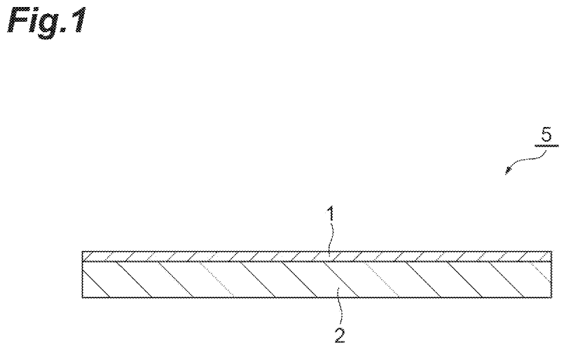

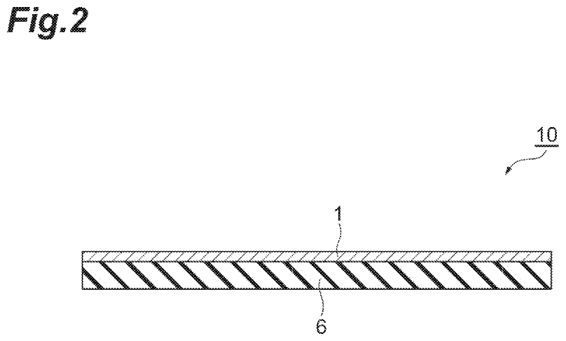

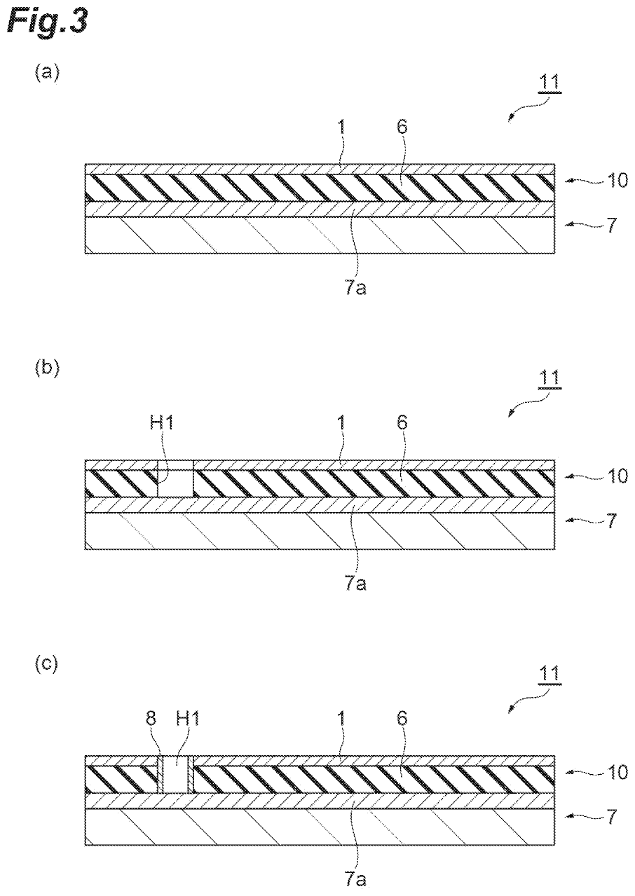

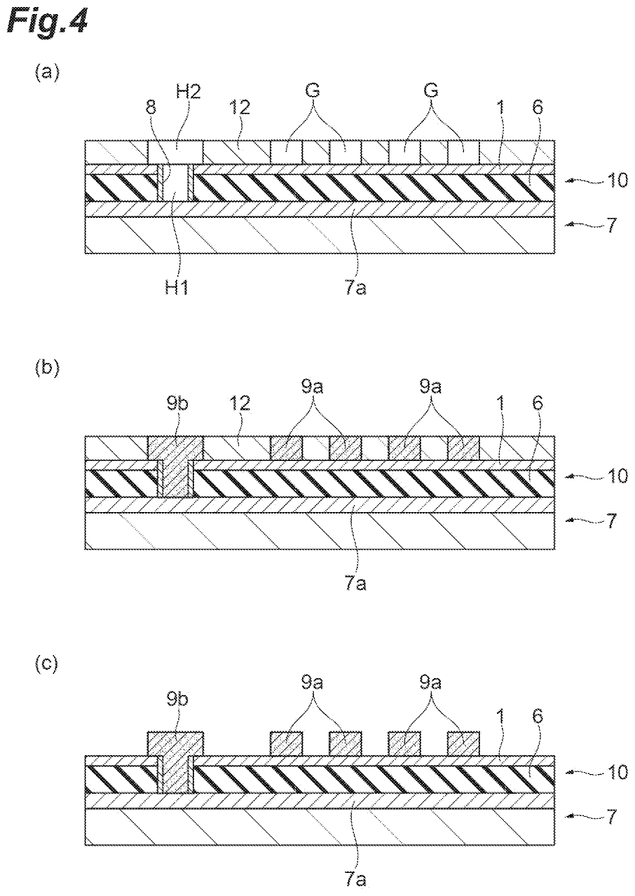

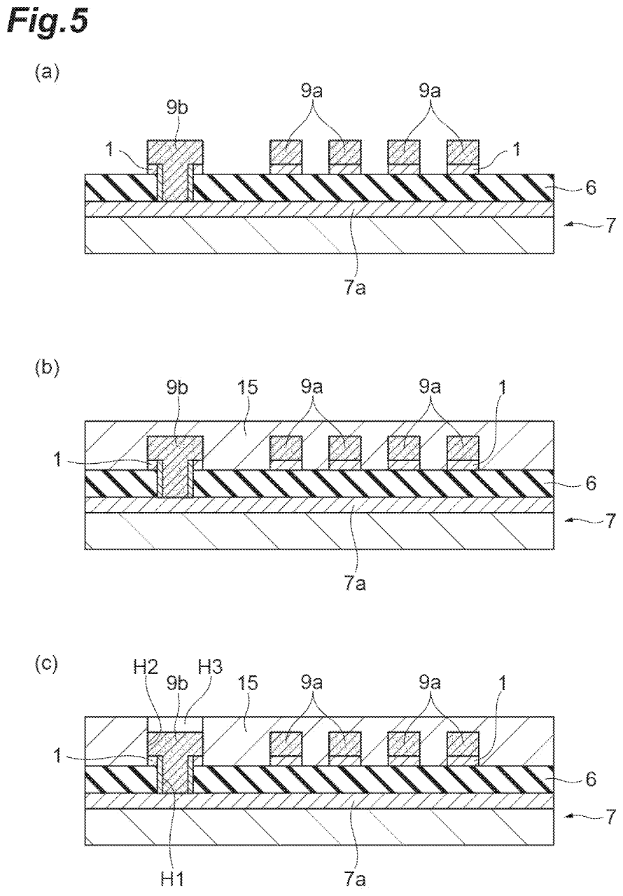

FIG. 1 is a cross-sectional view schematically illustrating a copper layer with carrier according to this embodiment. A copper layer with carrier 5 as shown in the drawing comprises a copper layer 1 formed by electroless copper plating and a carrier 2 provided in a peelable manner with respect to the copper layer 1. In this embodiment, the copper layer with carrier 5 is also used to transfer the copper layer 1 to an insulating material layer 6 to be described later (refer to FIG. 2).

(Copper Layer)

The copper layer 1 is a copper layer (electroless copper plating layer) formed by electroless plating. The electroless copper plating layer may contain nickel, phosphorus, boron, palladium, or the like in addition to copper that is a main component. Whether or not the copper layer 1 is formed by the electroless copper plating can be confirmed by element analysis of the copper layer 1.

The thickness of the copper layer 1 is preferably 20 nm to 200 nm, more preferably 40 nm to 200 nm, and still more preferably 60 nm to 200 nm. When the thickness of the copper layer 1 is 20 nm or more, the copper layer 1 tends to sufficiently play a role as a seed layer of electrolytic copper plating in manufacturing processes of a wiring board. On the other hand, when the thickness is 200 nm or less, the amount of etching of the copper layer 1 in the manufacturing processes of the wiring board is reduced, and fine wirings with a small variation in cross-sectional dimensions tend to be stably formed.

(Carrier)

The carrier 2 is provided in a peelable manner with respect to the copper layer 1. Although not particularly limited, the carrier 2 is preferably a flexible film. Specific examples of the carrier 2 include a polyethylene terephthalate (PET) film, a silicone film, and the like. The thickness of the carrier 2 is preferably within a range of 0.2 mm to 2.0 mm. When the thickness is 0.2 mm or more, handling tends to be satisfactory. On the other hand, when the thickness is 2.0 mm or less, the material cost tends to be suppressed.

For example, a shape of the carrier 2 may be a wafer shape (an approximately circular shape), a panel shape (a rectangular shape or a square shape). In a case of the wafer shape, a diameter is, for example, 200 to 450 mm, and may be 300 mm or 450 mm. In a case of the panel shape, a length of one side may be, for example, 300 to 700 mm.

[Method for Manufacturing Copper Layer with Carrier]

The copper layer with carrier 5 is manufactured through a process of forming the copper layer 1 on a surface of the carrier 2 by electroless copper plating. Hereinafter, a method for forming the copper layer 1 will be described.

Prior to a process of causing palladium (catalyst of the electroless copper plating) to be adsorbed to the surface of the carrier 2, the following processes are carried out. First, the surface of the carrier 2 is washed with a pretreatment solution. The pretreatment solution may be a commercially available alkaline pretreatment solution containing sodium hydroxide or potassium hydroxide. A concentration of the sodium hydroxide or the potassium hydroxide is, for example, 1% to 30%. Time for immersing the carrier 2 in the pretreatment solution is, for example, 1 minute to 60 minutes. An immersing temperature is, for example, 25° C. to 80° C. After the pretreatment, the carrier 2 may be washed with city water, pure water, ultrapure water, or an organic solvent in order to remove surplus pretreatment solution.

After removing the pretreatment solution, the carrier 2 is immersed and washed with an acidic aqueous solution in order to remove alkali ions on the surface of the carrier 2. As the acidic aqueous solution, for example, a sulfuric acid aqueous solution with a concentration 1% to 20% is used. Immersion time is, for example, 1 minute to 60 minutes. After immersion, the carrier 2 may be washed with city water, pure water, ultrapure water, or an organic solvent in order to remove the acidic aqueous solution.

Palladium is caused to adhere to the surface of the carrier 2 after being immersed and washed. For example, commercially available palladium-tin colloid solution, an aqueous solution containing palladium ions, or a palladium ion suspension may be used. Among these, the aqueous solution containing palladium ions is preferable from the viewpoint that palladium can be effectively adsorbed to the surface of the carrier 2. When immersing the carrier 2 in the aqueous solution, a temperature of the aqueous solution is, for example, 25° C. to 80° C., and immersion time is, for example, 1 minute to 60 minutes. After causing the palladium ions to be adsorbed, the carrier 2 may be washed with city water, pure water, ultrapure water, or an organic solvent in order to remove surplus palladium ions.

After palladium ion adsorption, activation for causing palladium ions to function as a catalyst is performed. A reagent for activating the palladium ions may be a commercially available activating agent (activation treatment solution). For example, the palladium ions can be activated by immersing the carrier 2 in the activating agent. A temperature of the activating agent is, for example, 25° C. to 80° C., and immersion time is, for example, 1 minute to 60 minutes. After activation of the palladium ions, the carrier 2 may be washed with city water, pure water, ultrapure water, or an organic solvent in order to remove a surplus activating agent.

Next, the copper layer 1 is formed on a surface of the carrier 2 by electroless copper plating. According to this, the copper layer with carrier 5 is obtained. Examples of the electroless copper plating include electroless pure copper plating (purity of 99% by mass or more), electroless copper nickel phosphorus plating (the content of nickel: 1% by mass to 10% by mass, and the content of phosphorus: 1% by mass to 13% by mass), and the like. From the viewpoint of securing satisfactory integrity, non-magnetic electroless copper plating is preferable. An electroless copper plating solution may be a commercially available plating solution, and for example, an electroless copper plating solution (trade name: THRU-CUP, manufactured by C. Uyemura & Co., Ltd.) can be used. The electroless copper plating is performed in the electroless copper plating solution kept at 25° C. to 60° C. After the electroless copper plating, the copper layer with carrier 5 may be washed with city water, pure water, ultrapure water, or an organic solvent in order to remove a surplus plating solution.

Note that, in a case where it is difficult to form the copper layer 1 on the surface of the carrier 2, the carrier 2 may be subjected to a surface treatment in advance. As the surface treatment method, modification by oxygen plasma, argon plasma, nitrogen plasma, ultraviolet-ozone, or the like is exemplified.

[Laminate]

FIG. 2 is a cross-sectional view schematically illustrating a laminate according to this embodiment. A laminate 10 shown in the drawing comprises an insulating material layer 6 and the copper layer 1 provided on a surface of the insulating material layer 6. The laminate 10 is obtained through a process of pasting the copper layer 1 of the copper layer with carrier 5 to a surface of the insulating material layer 6, and a process of peeling the carrier 2 from the copper layer 1. That is, the laminate 10 is obtained by transferring the copper layer 1 of the copper layer with carrier 5 to the surface of the insulating material layer 6.

Examples of the method of pasting the copper layer 1 of the copper layer with carrier 5 to the insulating material layer 6 include atmospheric pressure pressing, vacuum pressing, vacuum laminating, roll laminating, vacuum roll laminating, and the like. Among these, the vacuum pressing is preferable from the viewpoint capable of pasting a large area at once. The copper layer 1 that can be pasted to the insulating material layer 6 by the methods has higher adhesiveness with respect to the insulating material layer 6 in comparison to the carrier 2. According to this, the carrier 2 can be easily peeled from the copper layer 1, for example, with hands.

(Insulating Material Layer)

For example, the insulating material layer 6 is constituted by a thermosetting insulating material. Examples of the thermosetting insulating material include a liquid or film-shaped article, and the film-shaped thermosetting insulating material is preferable from the viewpoint of flatness of a film thickness and the cost. From the viewpoint capable of forming fine wirings, it is preferable that the thermosetting insulating material contains a filler having an average particle size of 500 nm or less (more preferably 50 to 200 nm). The content of the filler in the thermosetting insulating material is preferably more than 0 part by mass and equal to or less than 70 parts by mass with respect to 100 parts by mass of thermosetting insulating material excluding the filler, and more preferably more than 0 part by mass and equal to or less than 50 parts by mass.

In a case of using the film-shaped thermosetting insulating material, it is preferable to use a thermosetting insulating film that can be pressed at 40° C. to 250° C. The thermosetting insulating film in which a vacuum pressing-possible temperature is 40° C. or higher has appropriately strong tackiness at an ordinary temperature (25° C.), and thus the thermosetting insulating film tends to have a satisfactory handleability. On the other hand, a thermosetting insulating film in which the vacuum pressing-possible temperature is 250° C. or lower tends to be able to suppress warpage after lamination.

A coefficient of thermal expansion of the insulating material layer 6 after being cured is preferably 80×10⁻⁶/K or less from the viewpoint of suppressing warpage, and more preferably 70×10⁻⁶/K or less from the viewpoint of obtaining high reliability. In addition, the coefficient of thermal expansion is preferably 50×10⁻⁶/K or more from the viewpoint of obtaining a stress relaxation property of the insulating material layer 6 and a high-definition pattern.

The thickness of the insulating material layer 6 is preferably 50 μm or less, more preferably 40 μm or less, and still more preferably 30 μm or less. When the thickness of the insulating material layer 6 is within the above-described range, for example, a fine opening H1 having a circular shape or an elliptical shape is easily formed in a satisfactory manner. The thickness of the insulating material layer 6 is preferably 1 μm or more from the viewpoint of insulation reliability.

[Method for Manufacturing Wiring Board]

A method for manufacturing a wiring board according to this embodiment will be described with reference to the accompanying drawings. A wiring board 20 shown in (c) in FIG. 5 is manufactured through the following processes.

(1) Providing a laminate 11 comprising the copper layer 1, the insulating material layer 6, and a support board 7 in this order (refer to (a) in FIG. 3).

The laminate 11 may be provided by preparing the laminate 10 comprising the copper layer 1 and the insulating material layer 6 in advance, and by laminating the support board 7 on the laminate 10, or may be provided by preparing a laminate comprising the insulating material layer 6 and the support board 7 in advance, and by transferring the copper layer 1 to the laminate from the copper layer with carrier 5. As the support board 7, for example, a copper clad laminate can be used, and a copper layer 7a is provided on a surface of the copper clad laminate.

(2) Forming an opening H1 (first opening) reaching a surface (copper layer 7a) of the support board 7 through the copper layer 1 and the insulating material layer 6 (refer to (b) in FIG. 3).

The opening H1 can be formed, for example, by irradiation with a laser. In a case where a residue is recognized in the opening H1, a desmear treatment may be performed after the process (2).

(3) Forming a seed layer 8 on a surface of a side wall of the opening H1 by electroless copper plating (refer to (c) in FIG. 3).

The seed layer 8 constitutes a seed layer for performing electrolytic plating in the following process (5) in combination with the copper layer 1.

(4) Forming a resist pattern 12 including an opening H2 (second opening) communicating with the opening H1 and a plurality of grooves G reaching the surface of the copper layer 1 on the surface of the copper layer 1 (refer to (a) in FIG. 4).

(5) Filling the opening H2 and the grooves G with a conductive material containing copper by electrolytic copper plating (refer to (b) in FIG. 4).

When the grooves G are filled with the conductive material containing copper by the electrolytic copper plating, a conductive portion 9a constituting a part of a fine wiring is formed. When the opening H1 and the opening H2 are filled with the conductive material containing copper by the electrolytic copper plating, a conductive portion 9b (a part of an interlayer conductive portion) is formed.

(6) A process of peeling the resist pattern 12 (refer to (c) in FIG. 4).

(7) A process of removing the copper layer 1 exposed due to peeling of the resist pattern 12 (refer to (a) in FIG. 5).

When an unnecessary portion of the copper layer 1 is removed, for example, by etching, a fine wiring is constituted by the conductive portion 9a and a remaining portion of the copper layer 1.

(8) A process of forming an insulating material layer 15 to cover a surface of the copper layer 7a and the fine wiring (refer to (b) in FIG. 5).

(9) A process of forming an opening H3 (third opening) reaching the conductive portion 9b in the insulating material layer 15 (refer to (c) in FIG. 5).

A via-hole is formed by the openings H1, H2, and H3. A wiring board is completed by filling the via-hole with a conductive material and through surface finish processing and the like.

Hereinbefore, the embodiment of the present disclosure has been described in detail, but the invention is not limited to the embodiment. For example, in the embodiment, a method of manufacturing a wiring board provided with one wiring layer constituted by the fine wiring and the insulating material layer 15 that covers the fine wiring has been exemplified, but a wiring board comprising a plurality of the wiring layers may be manufactured. A multilayer wiring layer can be manufactured by performing the series of processes (2) to (9) one or more times by using the laminate 10 instead of the laminate 11 in the process (1) after the above-described process (9).

### EXAMPLES

Hereinafter, the present disclosure will be described on the basis of examples. Note that, the invention is not limited to the following examples.

### Example 1A

<Preparation of Copper Layer with Carrier>

An electroless copper plating layer was formed on a surface of a polyethylene terephthalate film (trade name: G2-16, manufactured by TEIJIN LIMITED, thickness: 16 μm, hereinafter, referred to as “carrier”) as a carrier as follows. First, the carrier was immersed in an acidic cleaner (trade name: MCD, manufactured by C.Uyemura & Co., Ltd.) at 40° C. for five minutes. Then, the carrier was immersed in pure water kept at 40° C. for one minute. Next, the carrier was immersed in 10% sulfuric acid aqueous solution at 25° C. for one minute. Then, the carrier was washed with flowing pure water kept at 25° C. for one minute. Next, the carrier was immersed in a pre-dip solution (trade name: MDP, manufactured by C.Uyemura & Co., Ltd.) kept at 25° C. for one minute. Next, the carrier was immersed in an activator solution (trade name: MAT, manufactured by C.Uyemura & Co., Ltd.) at 40° C. for five minutes. Then, the carrier was washed with flowing pure water kept at 25° C. for one minute. Next, the carrier was immersed in a reducer solution (trade name: MAB, manufactured by C.Uyemura & Co., Ltd.) at 35° C. for three minutes. Next, the carrier was washed with flowing pure water kept at 25° C. for one minute. Then, the carrier was immersed in an accelerator solution (trade name: MEL, manufactured by C.Uyemura & Co., Ltd.) at 25° C. for one minute. Then, the carrier was immersed in an electroless copper plating solution (trade name: PEAV2, manufactured by C.Uyemura & Co., Ltd.) at 36° C. for five minutes. According to this, a copper layer was caused to precipitate onto a surface of the carrier. A copper layer with carrier obtained through the processes was immersed in pure water for one minute, and then the copper layer with carrier was dried on a hot plate kept at 85° C. for five minutes.

### Example 2A

A copper layer with carrier was prepared in a similar manner as in Example 1A except that immersion time in the electroless copper plating solution was set to 10 minutes instead of five minutes.

### Example 3A

A copper layer with carrier was prepared in a similar manner as in Example 1A except that immersion time in the electroless copper plating solution was set to 20 minutes instead of five minutes.

### Example 4A

A copper layer with carrier was prepared in a similar manner as in Example 1A except that immersion time in the electroless copper plating solution was set to 40 minutes instead of five minutes.

<Measurement of Thickness of Copper Layer>

The thickness of the copper layer (electroless copper plating layer) in the copper layers with carrier according to Examples 1A to 4A was measured through cross-sectional observation by scanning electron microscope (Regulus 8930, manufactured by Hitachi High-Tech Corporation). Results are shown in Table 1.

TABLE 1

| | Electroless copper | Thickness of |
|---|---|---|
| | plating time | copper layer |
| Example 1A | 5 minutes | 60 nm |
| Example 2A | 10 minutes | 120 nm |
| Example 3A | 20 minutes | 180 nm |
| Example 4A | 40 minutes | 200 nm |

### Example 1B

<Preparation of Thermosetting Resin Film>

First, a thermosetting resin composition was prepared by using the following components.
Biphenyl aralkyl type epoxy resin (trade name: NC-3000H, manufactured by Nippon Kayaku Co., Ltd.): 70 parts by mass
Curing agent: a curing agent including a sulfone group in a molecular main chain, and including an acidic substituent group and an unsaturated N-substituted maleimide group: 30 parts by mass

The curing agent was synthesized as follows. That is, the following compounds were put into a reactor (volume: 2 liters) equipped with a thermometer, a stirrer, and a reflux condensing tube, and the compounds were caused to react with each other at 140° C. for five hours. Note that, as the reactor, a reactor that can be heated and cooled and includes a moisture meter was used.

Bis(4-aminophenyl) sulfone: 26.40 g

2,2′-bis[4-(4-maleimidephenoxy)phenyl] propane: 484.50 g

p-aminobenzoic acid: 29.10 g

dimethylacetamide: 360.00 g
Inorganic filler component: silica filler (average particle size: 50 nm, silane coupling treated with vinyl silane)

The silica filler was blended to be 30% by mass on the basis of the total mass of the resin component. A particle size distribution of the silica filler was measured by using a dynamic light scattering nanotrack particle size distribution meter “UPA-EX150” (manufactured by NIKKISO CO., LTD.) and a laser diffraction scattering microtrack particle size distribution meter “MT-3100” (manufactured by NIKKISO CO., LTD.), and it was confirmed that a maximum particle size became 1 μm or less.

A thermosetting resin composition solution having the above-described composition was applied onto a surface of a polyethylene terephthalate film (trade mane: G2-16, manufactured by TEIJIN LIMITED, thickness: 16 μm, hereinafter, referred to as “PET film”). A coated film was dried at 100° C. for approximately 10 minutes by using a hot wind connection type drier. A thermosetting resin film having a thickness of 10 μm was formed on the PET film.

<Preparation of Laminate>

As a support board, a wiring board (size: 200 mm square, thickness: 1.5 mm) containing glass cloth was prepared. The support board includes a copper layer having a thickness of 20 μm on a surface thereof. The support board, the thermosetting resin film (insulating material layer), and the copper layer with carrier according to Example 1A were placed in this order, and were pressed by using a press type vacuum laminator (MVLP-500, manufactured by Meiki Co., Ltd.). As press conditions, a press hot plate temperature was set to 70° C., vacuum drawing time was set to 20 seconds, a laminate press time was set to 40 seconds, an atmospheric pressure was set to 4 kPa or lower, and a compression pressure was set to 0.5 MPa. Next, additional pressing was performed by using a press machine. Press conditions were as follows. A temperature was raised to 220° C. during press time of 0 to 60 minutes, the temperature was maintained at 220° C. during press time of 60 to 190 minutes, and the temperature was lowered to 25° C. during press time of 190 to 220 minutes. A press pressure was set to 2.0 MPa and an atmospheric pressure was set to 4 kPa. After press processing, the carrier was peeled from the copper layer.

<Preparation of Wiring Board>

A via processing was performed by using a laser processing machine (product name: LC-2K21, manufactured by Via Mechanics, Ltd.) to form a first opening reaching a surface of the wiring board. Via processing conditions were an aperture diameter of 6.5 mm, an output of 6.3 W, a pulse pitch of 20 μm×three times, and a burst mode. A copper layer (seed layer) was formed on a surface of a side wall of the opening by electroless plating. The electroless plating was performed by the same method as in formation of the electroless copper plating layer on the surface of the carrier.

A wiring forming resist (RY-5107UT, manufactured by Showa Denko Materials Co., Ltd.) was vacuum-laminated on the surface of the copper layer (thickness: 60 nm) according to Example 1A by using a vacuum laminator (V-160, manufactured by Nikko-Materials Co., Ltd.). A lamination temperature was set to 110° C., lamination time was set to 60 seconds, and a lamination pressure was set to 0.5 MPa.

After the vacuum lamination, the resultant laminate was left as is for one day, and the wiring forming resist was exposed by using i-line stepper exposing machine (product name: S6CK type exposing machine, lens: ASC3(Ck), manufactured by CERMA PRECISION, INC.). An exposure amount was set to 140 mJ/cm², and focus was set to −15 μm. After the exposure, the resultant laminate was left as is for one day, a protective film of the wiring forming resist was peeled off, and development was performed by using a spray developing machine (AD-3000, manufactured by Mikasa Co., Ltd). As a developing solution, 1.0% sodium carbonate aqueous solution was used. A developing temperature was set to 30° C., and a spray pressure was set to 0.14 MPa. According to this, a resist pattern for forming wirings of the following L/S (line/space) was formed on the copper layer according to Example 1A.
L/S=100 μm/100 μm (the number of wirings: 10)
L/S=80 μm/80 μm (the number of wirings: 10)
L/S=30 μm/30 μm (the number of wirings: 10)
L/S=10 μm/10 μm (the number of wirings: 10)
L/S=1 μm/1 μm (the number of wirings: 10)

Note that, a second opening communicating the first opening was also formed in the wiring forming resist.

The laminate was immersed in 100 mL/L aqueous solution of a cleaner (trade name: ICP clean S-135, manufactured by OKUNO Chemical Industries Co., Ltd.) at 50° C. for one minute, and was immersed in pure water at 50° C. for one minute. Next, the laminate was immersed in pure water at 25° C. for one minute, and was immersed in 10% sulfuric acid aqueous solution at 25° C. for one minute. Next, electrolytic copper plating was performed with respect to the laminate as follows. An aqueous solution was prepared by adding 0.25 mL of hydrochloric acid, 10 mL of Top Luchina GT-3 (trade name, manufactured by OKUNO Chemical Industries Co., Ltd.), 1 mL of Top Luchina GT-2 (trade name, manufactured by OKUNO Chemical Industries Co., Ltd.) to 7.3 L of aqueous solution of 120 g/L of copper sulfate pentahydrate and 220 g/L of 96% sulfuric acid. Electrolytic plating was performed with respect to a surface of the laminate by using the aqueous solution under the following conditions. The copper layer according to Example 1A was used as a seed layer. Then, the laminate was immersed in pure water at 25° C. for five minutes, and the laminate was dried on a hot plate kept at 80° C. for five minutes.

Temperature: 25° C.

Current density: 1.5 A/dm²

Time: 10 minutes

The wiring forming resist was peeled off by using a spray developing machine (AD-3000, manufactured by Mikasa Co., Ltd). 2.38% TMVAH aqueous solution was used as a peeling solution, a peeling temperature was set to 40° C., and a spray pressure was set to 0.2 MPa.

The copper layer (seed layer) according to Example 1A which was exposed due to peeling-off of the resist. In order to remove the copper layer, an aqueous solution having the following composition was prepared.

Etching solution (SAC-700W3C, manufactured by JCU CORPORATION): 5% by volume

98% sulfuric acid: 4% by volume

35% hydrogen peroxide solution: 5% by volume

Copper sulfate-pentahydrate: 30 g/L

The wiring board was immersed in the aqueous solution at 35° C. for one minute. The wiring board according to Example 1B was obtained by removing an unnecessary portion of the copper layer (refer to (a) in FIG. 5). Then, the wiring board was immersed in pure water at 25° C. for five minutes, and was dried on a hot plate kept at 80° C. for five minutes.

### Examples 2B to 4B

Wring boards according to Examples 2B to 4B were prepared in a similar manner as in Example 1B except that copper layers with carrier according to Examples 2A to 4A were respectively used instead of the copper layer with carrier according to Example 1A.

### Comparative Examples 1 to 3

Three kinds of copper foils with carrier (manufactured by MITSUI MINING & SMELTING CO., LTD.) were prepared. The copper foils were rolled copper foils, and the thicknesses thereof were as follows.

Thickness of copper foil of Comparative Example 1: 5 μm

Thickness of copper foil of Comparative Example 2: 10 μm

Thickness of copper foil of Comparative Example 3: 20 μm

Wring boards according to Examples 1 to 3 were respectively prepared in a similar manner as in Example 1B except that a copper foil that is a copper foil with carrier according to Comparative Examples 1 to 3 were respectively used instead of the copper layer (electroless copper plating layer) of the copper layer with carrier according to Example 1A.

<Evaluation of Wring Formability>

Before and after removing the seed layer, wiring formability was evaluated by using cross-sectional areas of the wirings according to examples and comparative examples on the basis of a microscope image.

That is, before and after removing the seed layer, an average value of cross-sectional areas of 10 wirings having L/S of 100 μm/100 μm was obtained. An average value of cross-sectional areas was also obtained with respect to 10 wirings having L/S of 80 μm/80 μm, L/S of 30 μm/30 μm, L/S of 10 μm/10 μm, and L/S of 1 μm/1 μm. The wiring formability was evaluated on the basis of the following reference.

Results are shown in Table 2.

A: Variation rate of the average value of the cross-sectional areas before and after removing the seed layer is less than 5%.

B: Variation rate of the average value of the cross-sectional areas before and after removing the seed layer is 5% or more and less than 10%.

C: Variation rate of the average value of the cross-sectional areas before and after removing the seed layer is 10% or more.

TABLE 2

| | Thickness of copper | L/S(μm/μm) | | | | |
|---|---|---|---|---|---|---|
| | layer or copper foil | 100/100 | 80/80 | 30/30 | 10/10 | 1/1 |
| Example 1B | 60 nm | A | A | A | A | A |
| Example 2B | 120 nm | A | A | A | A | A |
| Example 3B | 180 nm | A | A | A | A | A |
| Example 4B | 200 nm | A | A | A | A | A |
| Comparative | 5 μm | B | B | C | C | C |
| Example 1 | | | | | | |
| Comparative | 10 μm | B | C | C | C | C |
| Example 2 | | | | | | |
| Comparative | 20 μm | B | C | C | C | C |
| Example 3 | | | | | | |

<Evaluation of Reliability of Fine Wiring>

The board after forming wirings was subjected to a temperature cycle test. That is, the board was put into a test device (manufactured by ESPEC CORP.), and the test was performed under the following conditions:

temperature: −65° C. to 150° C.,

holding time: 15 minutes, and

1000 cycles.

An interface between the seed layer and the electrolytic plating layer in a cross-section of the wiring after the test was analyzed with a field emission type scanning electron microscope (FE-SEM) (Regulus 8230, manufactured by Hitachi High-Tech Corporation) to confirm presence or absence of peeling at the interface. Reliability of the fine wiring was evaluated on the basis of the following reference. Results are shown in Table 3.

A: Peeling is not recognized in all of ten wirings.

B: Peeling is recognized in one to three wirings among the ten wirings.

C: Peeling is recognized in four wirings or more among the ten wirings.

TABLE 3

| | Thickness of copper | L/S(μm/μm) | | | | |
|---|---|---|---|---|---|---|
| | layer or copper foil | 100/100 | 80/80 | 30/30 | 10/10 | 1/1 |
| Example 1B | 60 nm | A | A | A | A | A |
| Example 2B | 120 nm | A | A | A | A | A |
| Example 3B | 180 nm | A | A | A | A | A |
| Example 4B | 200 nm | A | A | A | A | A |
| Comparative | 5 μm | C | C | C | C | C |
| Example 1 | | | | | | |
| Comparative | 10 μm | B | C | C | C | C |
| Example 2 | | | | | | |
| Comparative | 20 μm | B | C | C | C | C |
| Example 3 | | | | | | |

### INDUSTRIAL APPLICABILITY

According to the present disclosure, a method for manufacturing a wiring board having excellent reliability is provided. In addition, according to the present disclosure, a laminate applicable to the manufacturing method and a manufacturing method thereof, and a copper layer with carrier are provided.

### REFERENCE SIGNS LIST

1: copper layer, 2: carrier, 5: copper layer with carrier, 6, 15: insulating material layer, 7: support board, 8: seed layer, 9a, 9b: conductive portion, 10, 11: laminate, 12: resist pattern, G: groove, H1: opening (first opening), H2: opening (second opening), H3: opening.

1. A method for manufacturing a wiring board, the method comprising:
(A1) providing a laminate comprising an insulating material layer and a copper layer provided on a surface of the insulating material layer, wherein the copper layer is an electroless copper plating layer;
(A2) forming a resist pattern on the surface of the copper layer, the resist pattern including a groove reaching a surface of the copper layer; and
(A3) filling the groove with a conductive material containing copper by electrolytic copper plating.

2. A method for manufacturing a wiring board, the method comprising:
(B1) providing a laminate comprising a support board, an insulating material layer, and a copper layer in order, wherein the copper layer is an electroless copper plating layer;
(B2) forming a first opening reaching a surface of the support board through the copper layer and the insulating material layer;
(B3) forming a seed layer on a surface of a side wall of the first opening by electroless copper plating;
(B4) forming a resist pattern on a surface of the copper layer, the resist pattern including a second opening communicating with the first opening; and
(B5) filling the first opening and the second opening with a conductive material containing copper by electrolytic copper plating.

3. The method according to claim 1, wherein a thickness of the copper layer is 20 nm to 200 nm.

4. The method according to claim 1, wherein the laminate is prepared by:
(b1) providing a copper layer with carrier which comprises the copper layer and the carrier that supports the copper layer;
(b2) pasting the copper layer onto a surface of the insulating material layer; and
(b3) peeling the carrier from the copper layer.

5. A method for manufacturing the laminate according to claim 6, the method comprising:
providing the copper layer with a carrier which comprises the copper layer and the carrier provided in a peelable manner with respect to the copper layer;
pasting the copper layer onto the surface of the insulating material layer; and
peeling the carrier from the copper layer.

6. A laminate comprising:
an insulating material layer; and
a copper layer provided on a surface of the insulating material layer,
wherein the copper layer is an electroless copper plating layer.

7. (canceled)

8. The method according to claim 2, wherein a thickness of the copper layer is 20 nm to 200 nm.

9. The method according to claim 2, wherein the laminate is prepared by:
(b1) providing a copper layer with carrier which comprises the copper layer and the carrier that supports the copper layer;
(b2) pasting the copper layer onto a surface of the insulating material layer; and
(b3) peeling the carrier from the copper layer.

10. The laminate according to claim 6, wherein a thickness of the copper layer is 20 nm to 200 nm.
